(19) United States
(12) Patent Application Publication
(10) Pub. No.: US 2004/0092112 A1
(43) Pub. Date: May 13, 2004

(54) Chemical mechanical polishing system and method for planarizing substrates in fabricating semiconductor devices

(76) Inventors: Chia-Lin Hsu, Taipei City (TW); Shao-Chung Hu, Taipei City (TW); Teng-Chun Tsai, Hsin-Chu City (TW)

Correspondence Address: DICKINSON WRIGHT PLLC, 1901 L. STREET NW, SUITE 800, WASHINGTON, DC, 20036, US

(21) Appl. No.: 10/699,527

(22) Filed: Oct. 31, 2003

Related U.S. Application Data
(63) Continuation of application No. 10/210,102, filed on Aug. 2, 2002.
Application No. 10/210,102 is a division of application No. 09/847,088, filed on May 2, 2001, now abandoned.

(51) Int. Cl. H01L 21/302; H01L 21/461

(52) U.S. Cl. 438/689

(57) ABSTRACT

In accordance with the present invention, a system for planarizing a substrate in fabricating semiconductor devices is provided. The system comprises at least two different types of polishing module which are arranged in an arbitrary sequence beginning with a first polishing module and ending with a last polishing module, means for transferring the substrate between the polishing modules, a load station, and an unload station. The load station is for loading the transferring means with the substrate prior to starting polishing at the first polishing module, and the unload station is for unloading the substrate from the transferring means after ending polishing at the last polishing module. A method for planarizing a substrate in fabricating semiconductor devices by using a polishing system is also provided. The system comprises at least two different types of polishing modules which are arranged in an arbitrary sequence beginning with a first polishing module and ending with a last polishing module, means for transferring the substrate, a load station, and an unload station. The method comprises the transferring means loads with the substrate at the load station prior to starting polishing at the first polishing module. Next, the substrate is sequentially polished and transferred in a sequence from the first polishing module to the last polishing module, and then the substrate is unloaded from the transferring means at the unload station after ending polishing at the last polishing module.

### BACKGROUND OF THE INVENTION

The present invention generally relates to a system and a method for semiconductor processes, and more particularly to a chemical mechanical polishing system and a method for planarizing substrates in fabricating semiconductor devices.

### DESCRIPTION OF THE PRIOR ART

As higher integration and miniaturization have been achieved in a semiconductor integrated circuit, miniaturization of a circuit pattern formed on a semiconductor wafer has also been proceeded. Slight irregularities on the wafer surface or on deposited films can distort semiconductor patterns, as which are transferred by a lithography process to the wafer surface. This non-planar surface presents a problem for manufacturing integrated circuit devices.

The etching step is typically prepared by placing a photoresist layer on the exposed surface of the substrate, and then selectively removing portions of the photoresist to provide the etch pattern on the layer. If the layer is non-planar, photolithographic techniques of patterning the photoresist layer might not be suitable because the surface of the substrate may be sufficiently non-planar to prevent focusing of the lithography apparatus on the entire layer surface. Therefore, periodically planarizing the substrate surface to restore a planar surface for lithography is an essential technique in the present device processing.

Chemical mechanical polishing or planarizing (CMP) is one widely accepted method of planarization. The main benefit of performing CMP is to achieve global as well as local planarity. Local planarity corresponds to providing planarization over small regions of the substrate surface, while global planarity corresponds to providing planarization over the entire substrate surface. In general, the CMP process involves pressing a semiconductor substrate against a moving polishing surface that is wetted with a chemically reactive, abrasive slurry. The polishing surface is typically a planar pad, which is usually mounted on a planar rotatable platen, but linear moving pads are also now being proposed. The combination of polishing pad characteristics, the specific slurry mixture, and other polishing parameters can provide specific polishing characteristics. Thus, for any material being polished, the pad and slurry combination is theoretically capable of providing a specified finish (lacks small-scale roughness) and flatness (lacks large-scale topography) on the polished surface.

However, it must be understood that additional polishing parameters, including the distribution of slurry under the substrate, the relative speed between the substrate and the polishing pad, the contour and condition of the polishing pad, the topography of the front face of the substrate, and the force pressing the substrate against the pad, affect the polishing rate, finish, and flatness. Thus, there have been several types of CMP developments, such as rotary type, orbital type, fixed-abrasive type, and linear type, to serve different polishing needs.

Referring to FIG. 1, a schematic view of a rotary CMP 100 is shown. A platen 120 is mounted to a support structure 110. A polishing surface (or polishing pad) 130 is positioned on the platen 120. A movable substrate carrier 140 is positionable over the polishing surface 130, wherein at least one of the platen 120 and the substrate carrier 140 moves with respect to the other to impart relative motion between the substrate 150 and the polishing pad 130. A liquid solution dispenser 160 being connected to a supply of polishing solution 170 to dispense the polishing solution (or slurry) on the polishing surface 130. During polishing, the substrate carrier 140 rotates in the direction of arrow A and the platen 120 can also rotate in the direction of arrow B. A rotary type is the most mature method of development of CMP; its polishing pad has a very large diameter as compared with the diameter of the substrate helps to in-situ condition the polishing pad. However, since the polishing rate applied to the substrate is proportional to the relative velocity between the substrate and the polishing pad, the polishing rate at a selected point on the substrate surface depends upon the distance of the selected point from the two primary axes of rotation, that of the substrate and that of the polishing pad, resulting in a non-uniform velocity profile across the surface of the substrate, and therefore, in a non-uniform polish.

The structure of the orbital CMP 200 is similar to that of the rotary type, as shown in FIG. 2, but with a relatively smaller polishing pad 230 of a diameter slightly larger than that of the substrate 250 which is held by a substrate carrier 240. In this type of CMP, by use of the dispenser 260, slurry 270 may be distributed to the substrate/polishing pad interface through a plurality of holes formed throughout the polishing pad 230 and the platen 220 which is mounted on a support structure 210. The rotating direction of the substrate carrier 240 and the platen 220 is indicated as arrow A and B, respectively. This improved design of a polishing pad and the greater uniformity in the distribution of slurry improves the uniformity of velocity profile across the surface of the substrate. However, due to the relative smaller polishing pad, an in-situ and in real-time conditioning process is infeasible while a wafer is being planarized. Thus, the orbital CMP is suitable for controlling the polishing non-uniformity and the barrier layer polish or buffing. The structure of the orbital CMP 200 is similar to that of the rotary type, as shown in FIG. 2, but with a relatively smaller polishing pad 230 of a diameter slightly larger than that of the substrate 250 which is held by a substrate carrier 240. In this type of CMP, by use of the dispenser 260, slurry 270 may be distributed to the substrate/polishing pad interface through a plurality of holes formed throughout the polishing pad 230 and the platen 220 which is mounted on a support structure 210. The rotating direction of the substrate carrier 240 and the platen 220 is indicated as arrow A and B, respectively. This improved design of a polishing pad and the greater uniformity in the distribution of slurry improves the uniformity of velocity profile across the surface of the substrate. However, due to the relative smaller polishing pad, an in-situ and in real-time conditioning process is infeasible while a wafer is being planarized. Thus, the orbital CMP is suitable for controlling the polishing non-uniformity and the barrier layer polish or buffing.

Planarizing solutions 370 without abrasive particles are used on the fixed-abrasive CMP with a higher planarity efficiency, which use a fixed-abrasive polishing pad 330 made from abrasive particles fixedly dispersed in a suspension medium, as shown in FIG. 3. During polishing, the substrate carrier 340 rotates in the direction of arrow A. A reoccurring problem with fixed-abrasive CMP is the scratching of the substrate surface. In some cases, the use of fixed-abrasive CMP creates shallow grooves in the substrate surface.

Referring to FIG. 4, a schematic view of a linear CMP 400 is shown. A substrate carrier 440 with substrate 450 is positioned on a belt 430, which moves about first and second rollers 410 and 420. A slurry dispenser 460 provides the slurry 470 on top of the belt. During polishing, the substrate carrier rotates in the direction of arrow A and the belt moves in a linear direction of arrow B. The linear CMP, instead of a rotating pad, a high-speed belt moves a pad linearly across the substrate to provide a high material removal rate and a more uniform velocity profile across the surface of the substrate. But the linear CMP is sensitive to the pattern density and has the problem of creating defects.

However, as the size of integrated circuits continues to shrink, the planarization technique applied to the manufacturing of semiconductor devices is pushed to its limitation. By using the conventional polishing system, which is integrated with certain type of CMPs with its pros and cons, with more complicated substrate processing, it doesn't match the need to optimize the planarization of substrate surface, which has different kinds of materials with different polishing characteristic. Transferring the substrate back and forth to different CMP systems is not a practical solution to the optimization of a multi-step process, the substrate must be repeatedly wetted, polished, and cleaned with different systems till the planarization is completed. The risk of contaminating substrates and time consumption presents a reduction in throughput. Therefore, it is a desire to provide a polishing system and a method to optimize the planarization of the substrate surface of integrating different types of CMP modules that bring specific advantages and requirements to optimize the polishing process.

### SUMMARY OF THE INVENTION

The present invention is directed to a chemical mechanical polishing system and a method for optimizing the planarization of the substrate surface by integrating different types of CMP modules with specific advantages to achieve the optimization of polishing process to fulfill the requirements of the semiconductor process.

It is another object of this invention that a system and a method for sequentially polishing a substrate surface by using at least two different types of polishing module are provided.

It is a further object of this invention that a system and a method for optimizing the polishing throughput, flatness, and finish while minimizing the risk of contamination or destruction of the substrate in fabricating semiconductor devices are provided.

It is another further object of this invention that a system and a method for integrating advantages of different types of CMP applied to the fabrication of semiconductor devices are provided. The multiple modules can be used in a multi-step polishing process in which the modules have different polishing characteristics and the substrates are subjected to progressively finer polishing.

It is yet another object of this invention that a system and a method for polishing a substrate comprise a cleaner for the purpose of cleaning the substrate dry-in/dry-out the system.

In accordance with the present invention, in one embodiment, a system and a method are provided for planarizing a substrate in fabricating semiconductor devices. The system comprises at least two different types of polishing modules, with means for transferring the substrate between the polishing modules, an unload station, and a load station. The two different types of polishing modules are arranged in an arbitrary sequence beginning with a first polishing module and ending with a last polishing module. One of the polishing modules comprises a cleaner for cleaning the substrate. The unload station is for unloading the substrate from the transferring means after ending polishing at the last polishing module. The load station is for loading the transferring means with the substrate prior to starting polishing at the first polishing module. The polishing modules comprise a polishing surface, a movable substrate carrier for holding the substrate being positionable over the polishing surface, and a liquid solution dispenser for dispensing a polishing solution on the polishing surface. At least one of the polishing surface and the substrate carrier moves with respect to the other to impart relative motion between the substrate and the polishing surface. The polishing system further comprises a cleaner for cleaning the substrate. A method for planarizing a substrate by using a polishing system in fabricating semiconductor devices is also provided, wherein the polishing system comprises at least two different types of polishing module, means for transferring the substrate, a load station, and an unload station. The polishing modules are arranged in an arbitrary sequence beginning with a first polishing module and ending with a last polishing module. The method comprises the transferring means loading with the substrate at the load station prior to starting polishing at the first polishing module. Next, the substrate is sequentially polished and transferred in a sequence from the first polishing module to the last polishing module, and then the substrate is unloaded from the transferring means at the unload station after ending polishing at the last polishing module. The polishing system further comprises a cleaner for cleaning the substrate. The method further comprises the step of cleaning the substrate at the cleaner.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic view of a rotary CMP;

FIG. 2 is a schematic view of an orbital CMP;

FIG. 3 is a schematic view of a fixed-abrasive CMP;

FIG. 4 is a schematic view of a linear CMP;

FIG. 5 is a schematic view of the present invention of square type;

FIG. 6 is a schematic view of the present invention of parallel type; and

FIG. 7 is a schematic view of the present invention of pentagon type.

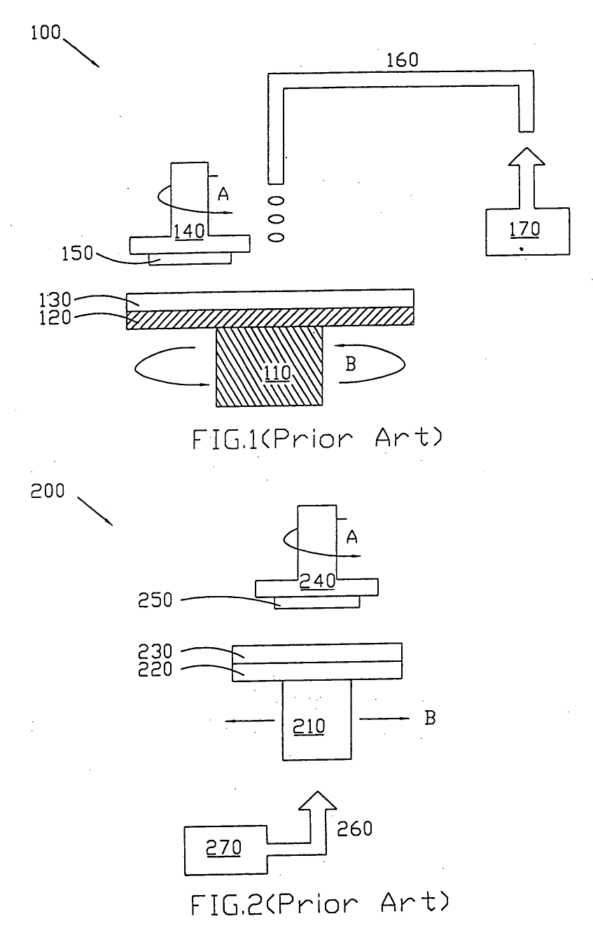

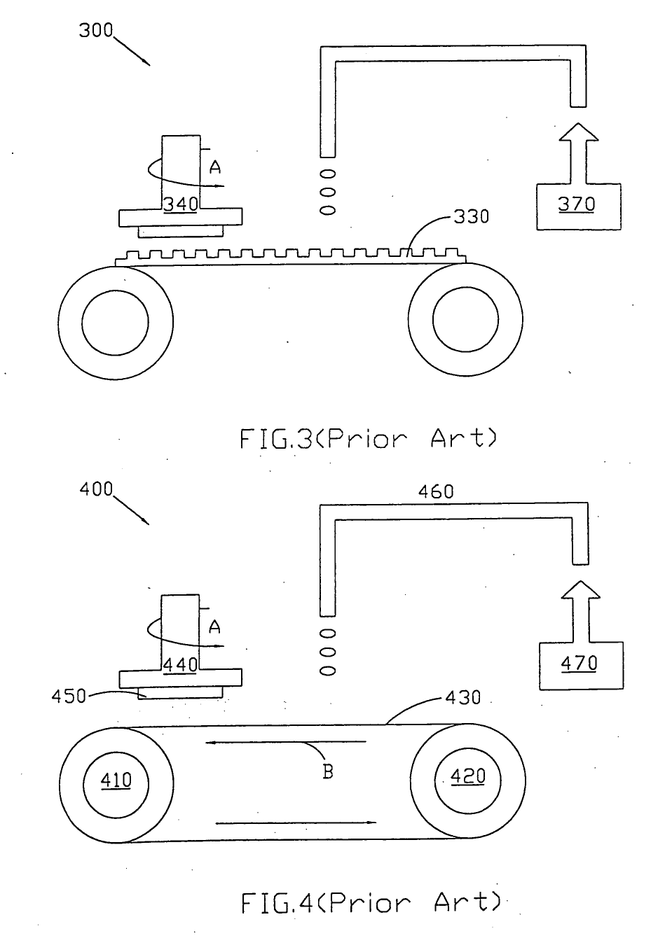

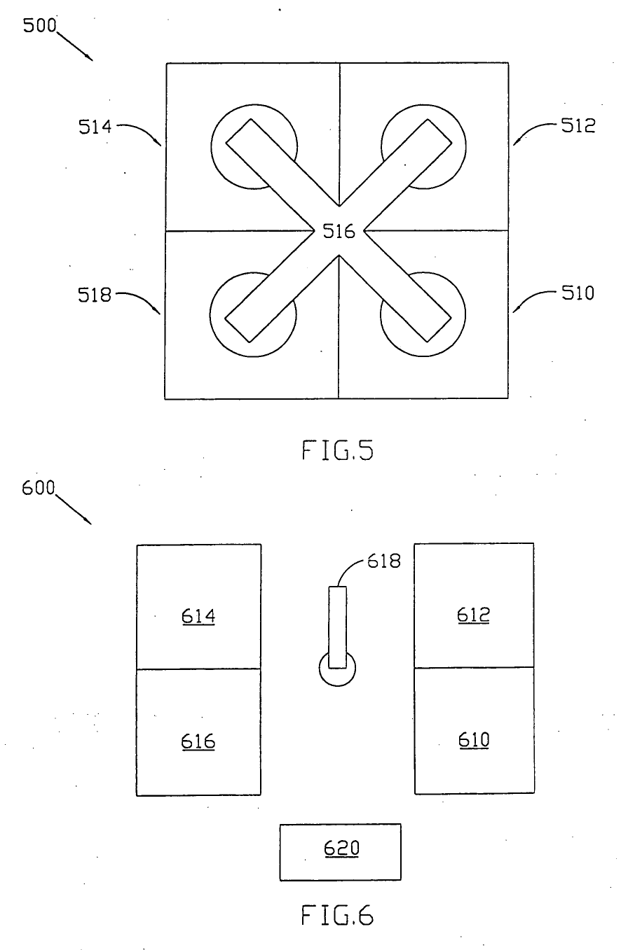

### DETAILED DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

The present invention is a polishing system and a method for polishing a substrate to optimize the planarization of the substrate surface in fabricating semiconductor devices. The substrate can be any substrate at any stage in the semiconductor processes, such as a semiconductor substrate, an insulation layer covered substrate, or a substrate in the metallization process. An important aspect of the present invention is to modulize every type of polisher and to integrate different types of polishing modules with specific advantages and characteristics to achieve the optimization of planarization in the polishing processes. The polishing modules comprise a polishing surface, a movable substrate carrier for holding the substrate being positioned over the polishing surface, and a liquid solution dispenser for dispensing a polishing solution on the polishing surface. At least one of the polishing surface and the substrate carrier moves with respect to the other to impart relative motion between the substrate and the polishing surface. The different types of polishing module comprise rotary, orbital, fixed-abrasive, and linear chemical mechanical polishers (CMP).

Referring to FIG. 5, in one embodiment, a polishing system 500 named square type comprises three polishing modules, 510, 512, and 514. The three polishing modules can be each of a different type or just two types, one type with two identical polishers arranged in an arbitrary sequence beginning with a first polishing module and ending with a last polishing module. A transferring means 516 is for transferring a substrate between the polishing modules. A load station 518 is for loading the transferring means 516 with the substrate prior to starting polishing at the first polishing module. An unload station 518 is for unloading the substrate from the transferring means 516 after ending polishing at the last polishing module. The load/unload station can be the same station 518.

For applying to a shallow trench isolation (STI) polishing process, a system of square type is adopted. The system comprises three different types of polishers similar to the prior art, a linear CMP 510, a rotary CMP 512, and an orbital CMP 514, arranged in an arbitrary sequence beginning with the linear CMP 510, the rotary CMP 512, and ending with the orbital CMP 514. A transferring means 516 is for transferring a substrate, such as an insulation layer covered substrate, between the polishing modules. The transferring means 516 comprises a plurality of carrier heads, such as a cross substrate carrier with four carrier heads. A load station 518 is for loading the transferring means 516 with the substrate prior to starting polishing at the linear CMP 510. An unload station 518 is for unloading the substrate from the transferring means after ending polishing at the orbital CMP 514. The load/unload station 518 is the same station. The system further comprises a controller (not shown) to control the movements of the transferring means 516. The system further comprises a cleaner for cleaning the substrate (not shown). With the advantages of high polishing rates of the linear CMP 510, the step height of the substrate surface can be quickly reduced to a certain stage without concern in scratching the surface and creating defects. By use of the rotary CMP 512 can continuously polish the substrate surface to the end point or to a predetermined thickness. Buffing the substrate surface can control the problem of creating a non-uniform surface by use of the orbital CMP 514. Thus, a finer planarization of the substrate surface is achieved by integrating the advantages of three different types of polishing modules.

A method for planarizing a substrate in the STI polishing process by using a polishing system 500 is also provided. The polishing system 500 comprises at least two different types of polishing modules, means 516 for transferring the substrate, a load station 518, and an unload station 518, as shown in FIG. 5. The polishing modules include a linear CMP 510, a rotary CMP 512, and an orbital CMP 514 arranged in an arbitrary sequence beginning with a first polishing module and ending with a last polishing module. The transferring means 516 can have a plurality of carrier heads, such as four. The load/unload station can be the same station 518. The method comprises the transferring means 516 loads the substrate at the load station 518 prior to starting polishing at the linear CMP 510. Next, the substrate is sequentially polished and transferred in a sequence from the linear CMP 510 to the orbital CMP 514. Then, the substrate is unloaded from the transferring means 516 at the unload station 518 after ending polishing at the orbital CMP 514.

The step of sequentially polishing and transferring the substrate comprises the step of transferring the substrate to the linear CMP 510 and polishing the substrate to reach a first stage at the linear CMP 510. Then, the substrate is transferred to the rotary CMP 512 and polished to the end point or a predetermined thickness at the rotary CMP 512. Next, the substrate is transferred to the orbital CMP 514 and the buffing process at the orbital CMP 514 is applied. After the buffing process is completed, the substrate is transferred to the unload station 518. The polishing system 500 further comprises a cleaner for cleaning the substrate. The method further comprises a step of cleaning the substrate at the cleaner to achieve the goal of substrate dry-in/dry-out the system.

In another embodiment, a polishing system comprises at least two different types of polishing modules is provided. Referring to FIG. 6, a polishing system named parallel type with four polishing modules 610, 612, 614, and 616 is shown. The four polishing modules can be each of a different type or classified in two types (each type with two identical polishers) or three types (one type with two identical polishers) arranged in an arbitrary sequence beginning with a first polishing module and ending with a last polishing module. A transferring means 618 is for transferring a substrate between the polishing modules. A load station 620 is for loading the transferring means 618 with the substrate prior to starting polishing at the first polishing module. An unload station 620 is for unloading the substrate from the transferring means 618 after ending polishing at the last polishing module. The load/unload station can be the same station 620. The system further comprises a cleaner (not shown) to clean the substrate after the polish of the last polishing module is completed.

For application to a copper layer polishing process, a system comprises two different types of polishers, a rotary CMP and an orbital CMP, arranged in an arbitrary sequence beginning with the rotary CMP and ending with the orbital CMP and a means for transferring the substrate between the polishing modules. A load station is for loading the transferring means with the substrate prior to starting polishing at the rotary CMP. An unload station is for unloading the substrate from the transferring means after ending polishing at the orbital CMP. The system further comprises a controller to control the movements of the transferring means (not shown). It is known that most metal structures are formed with a glue layer (or barrier layer) deposited underneath a top metal layer so as to act as an adhesion layer and to provide low electrical resistance. The barrier layer is very different than the top metal layer. Accordingly, the polishing behavior of the barrier layer can be quite different than its respective top metal layer. With the advantage of high polishing rate of the rotary CMP, the substrate surface can be polished to a predetermined thickness or the end point without concerning of scratching the surface and creating defects. Then, the relative thinner barrier layer is removed by way of the orbital CMP. Thus, a finer planarization of the substrate surface is achieved by integrating the advantages of the rotary CMP and the orbital CMP.

A method for planarizing a substrate in the copper polishing process by using a polishing system is also provided. The polishing system comprises at least two different types of polishing modules, means for transferring the substrate, a load station, and an unload station. The polishing modules include a rotary CMP and an orbital CMP are arranged in a sequence beginning with the rotary CMP and ending with the orbital CMP. The transferring means can have a plurality of carrier heads. The load/unload station can be the same station. The method comprises the transferring means loads with the substrate at the load station prior to starting polishing at the rotary CMP. Next, the substrate is sequentially polished and transferred in a sequence from the rotary CMP to the orbital CMP. Then, the substrate is unloaded from the transferring means at the unload station after ending polishing at the orbital CMP.

The step of sequentially polishing and transferring comprises the step of transferring the substrate to the rotary CMP and polishing the substrate to reach a predetermined thickness at the rotary CMP. Then, the substrate is transferred to the orbital CMP and applied the buffing process at the orbital CMP. The polishing system further comprises a cleaner for cleaning the substrate. The method further comprises the step of cleaning the substrate. After the buffing process is completed, the substrate is transferred to the unload station.

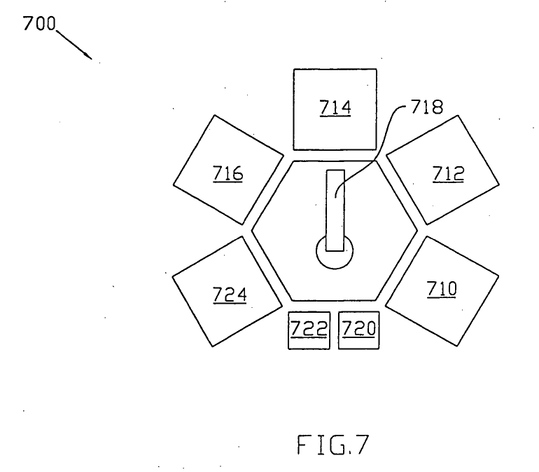

Referring to FIG. 7, in another embodiment, a system 700 for planarizing a substrate is provided. The system comprises at least two different types of polishing module arranging in an arbitrary sequence beginning with a first polishing module and ending with a last polishing module. The polishing system named pentagon type with four polishing modules, 710, 712, 714, and 716 are arranged in a counterclockwise sequence. One of the polishing modules comprises a cleaner 724 for cleaning the substrate. A transferring means 718 is for transferring a substrate between the polishing modules. A load station 720 is for loading the transferring means 718 with the substrate prior to starting polishing at the first polishing module. An unload station 722 is for unloading the substrate from the transferring means 718 after ending polishing at the last polishing module. The system 700 further comprises a controller to control the movements of the transferring means 718. By integrating advantages of different types of polishing modules, the multi-module polishing system can be used in a multi-step process in which the modules have different polishing characteristics and the substrates are subjected to progressively finer polishing.

Although specific embodiments have been illustrated and described, it will be obvious to those skilled in the art that various modifications may be made without departing from what is intended to be limited solely by the appended claims.

What is claimed is:

1. A system for polishing a substrate in fabricating semiconductor devices, said system comprising:
at least two different types of polishing module arranging in an arbitrary sequence beginning with a first polishing module and ending with a last polishing module;
means for transferring said substrate between said polishing modules;
an unload station for unloading said substrate from said transferring means after ending polishing at said last polishing module; and
a load station for loading said transferring means with said substrate prior to starting polishing at said first polishing module.

2. The system according to claim 1, wherein said polishing modules comprise:
a polishing surface;
a movable substrate carrier for holding said substrate being positionable over said polishing surface, wherein at least one of said polishing surface and said substrate carrier moves with respect to the other to impart relative motion between said substrate and said polishing surface; and
a liquid solution dispenser for dispensing a polishing solution on said polishing surface.

3. The system according to claim 1, wherein said transferring means comprises a plurality of carrier heads for holding said substrate.

4. The system according to claim 1, wherein said polishing modules comprises a rotary chemical mechanical polishing, and an orbital chemical mechanical polisher.

5. The system according to claim 1, further comprising a controlling for controlling movements of said transferring means.

6. The system according to claim 1, further comprising a cleaner for cleaning said substrate.

7. The system according to claim 1, wherein one of said polishing module comprises a cleaner for cleaning said substrate.

8. A method for planarizing a substrate by using a polishing system in fabricating semiconductor devices, wherein said system comprises at least two different types of polishing module, means for transferring said substrate, a load station, and an unload station, wherein said modules are arranged in an arbitrary sequence beginning with a first polishing module and ending with a last polishing module, said method comprising:
loading said transferring means with said substrate at said load station;
sequentially polishing and transferring said substrate in a sequence from said first polishing module to said last polishing module; and
unloading said substrate from said transferring means at said unload station after ending polishing at said last polishing module.

9. The method according to claim 8, wherein said polishing modules comprises a rotary chemical mechanical polisher, and an orbital chemical mechanical polisher.

10. The method according to claim 9, wherein said step of sequentially polishing and transferring said substrate comprises:
transferring said substrate to said rotary chemical mechanical polisher;
polishing said substrate at said rotary chemical mechanical polisher to reach a first stage;
transferring said substrate to said orbital chemical mechanical polisher after said first stage is reached;
polishing said substrate at said orbital chemical mechanical polisher to reach a second stage; and
transferring said substrate to said unload station after said second stage is reached.

11. The method according to claim 8, wherein said polishing system further comprises a cleaner for cleaning said substrate.

12. The method according to claim 11, further comprises a step of cleaning said substrate at said cleaner.

13. The method according to claim 8, wherein one of said polishing modules comprises a cleaner for cleaning said substrate.

14. A method for planarizing a substrate by using a polishing system in fabricating semiconductor devices, wherein said system comprises a first polishing module, a second polishing module, means for transferring said substrate, a load station, and an unload station, wherein said first polishing modules and said second polishing module are arranged in a sequence beginning with said first polishing module and ending with said second polishing module, said method comprising:
loading said transferring means with said substrate at said load station;
sequentially polishing and transferring said substrate in a sequence from said first polishing module to said second polishing module; and
unloading substrate from said transferring means at said unload station after ending polishing at said second polishing module.

15. The method according to claim 14, wherein said first polishing module is selected from the group consisting of a rotary type, an orbital type, a fixed-abrasive type, and a linear type chemical mechanical polishers.

16. The method according to claim 14, wherein said second polishing module is selected from the group consisting of a rotary type, an orbital type, a fixed-abrasive type, and a linear type chemical mechanical polishers.

17. The method according to claim 14, wherein said step of sequentially polishing and transferring said substrate comprises:
transferring said substrate to said first polishing module;
polishing said substrate at said first polishing module to reach a first stage;
transferring said substrate to said second polishing module after said first stage is reached;
polishing said substrate at said second polishing module to reach a second stage; and
transferring said substrate to said unload station after said second stage is reached.

18. The method according to claim 14, wherein said polishing system comprises a cleaner for cleaning said substrate.

19. The method according to claim 18, further comprising a step of cleaning said substrate at said cleaner.

20. The method according to claim 14, wherein said second polishing module comprises a cleaner for cleaning said substrate.
